(19) United States
(12) Patent Application Publication
(10) Pub. No.: US 2024/0260197 A1
(43) Pub. Date: Aug. 1, 2024

(54) WIRING SUBSTRATE

(71) Applicant: IBIDEN CO., LTD., Ogaki (JP)

(72) Inventors: Nobuhisa KURODA, Ogaki (JP); Tomoya DAIZO, Ogaki (JP)

(73) Assignee: IBIDEN CO., LTD., Ogaki (JP)

(21) Appl. No.: 18/428,062

(22) Filed: Jan. 31, 2024

(30) Foreign Application Priority Data
Feb. 1, 2023 (JP) 2023-014166

(51) Int. Cl. H05K 1/18; H01L 23/498; H01L 25/16; H01L 23/00

(52) U.S. Cl. CPC H05K 1/186; H01L 23/49838; H01L 25/16; H01L 24/13; H01L 24/16; H01L 2224/13111; H01L 2224/13147; H01L 2224/13155; H01L 2224/16227; H05K 1/181; H05K 2201/10015; H05K 2201/10022; H05K 2201/1003; H05K 2201/10159; H05K 2201/10977

(57) ABSTRACT

A wiring substrate includes a first insulating layer, a first conductive layer laminated on a surface of the first insulating layer and including pads, a second insulating layer laminated on the first insulating layer such that the second insulating layer is covering the first conductive layer and has a cavity exposing the pads of the first conductive layer, an electronic component accommodated in the cavity of the second insulating layer such that the electronic component has electrodes formed on a surface of the electronic component, and a conductive connecting part formed between the electrodes of the electronic components and the pads of the first conductive layer in the cavity of the second insulating layer such that the conductive connecting part electrically connects the electrodes of the electronic components and the pads of the first conductive layer.

### CROSS-REFERENCE TO RELATED APPLICATIONS

The present application is based upon and claims the benefit of priority to Japanese Patent Application No. 2023-014166, filed Feb. 1, 2023, the entire contents of which are incorporated herein by reference.

### BACKGROUND OF THE INVENTION

### Field of the Invention

The present invention relates to a wiring substrate having an internal cavity in which an electronic component is accommodated.

### Description of Background Art

For example, Japanese Patent Application Laid-Open Publication No. 2019-192730 describes a wiring substrate having an internal cavity in which an electronic component is accommodated. The entire contents of this publication are incorporated herein by reference.

### SUMMARY OF THE INVENTION

According to one aspect of the present invention, a wiring substrate includes a first insulating layer, a first conductive layer laminated on a surface of the first insulating layer and including pads, a second insulating layer laminated on the first insulating layer such that the second insulating layer is covering the first conductive layer and has a cavity exposing the pads of the first conductive layer, an electronic component accommodated in the cavity of the second insulating layer such that the electronic component has electrodes formed on a surface of the electronic component, and a conductive connecting part formed between the electrodes of the electronic components and the pads of the first conductive layer in the cavity of the second insulating layer such that the conductive connecting part electrically connects the electrodes of the electronic components and the pads of the first conductive layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an enlarged cross-sectional view of a wiring substrate according to an embodiment of the present invention;

FIG. 2 is a perspective view of an electronic component;

FIG. 3 is an enlarged cross-sectional view of a connecting portion between an electronic component and pads;

FIG. 4 is a cross-sectional view of a granule;

FIGS. 5A-5D are cross-sectional views illustrating a method for manufacturing a wiring substrate according to an embodiment of the present invention;

FIGS. 6A-6C are cross-sectional views illustrating the method for manufacturing a wiring substrate according to an embodiment of the present invention;

FIGS. 7A-7C are cross-sectional views illustrating a method for manufacturing a wiring substrate according to an embodiment of the present invention;

FIGS. 8A and 8B are cross-sectional views illustrating a method for manufacturing a wiring substrate according to an embodiment of the present invention; and

FIG. 9 is an enlarged cross-sectional view of a wiring substrate according to a second embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

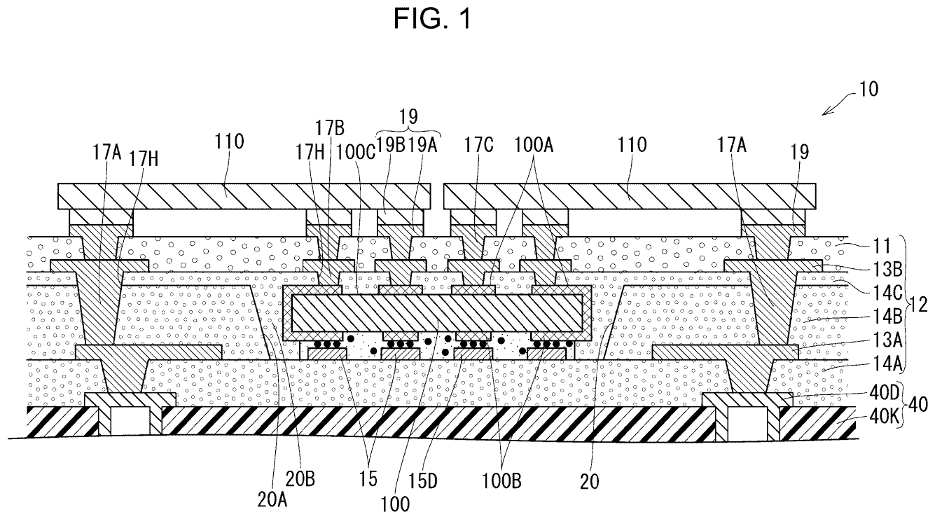

In the following, an embodiment of the present invention is described with reference to FIGS. 1-8. A wiring substrate 10 of the present embodiment illustrated in FIG. 1 includes a core substrate 40 and build-up parts 12 that are respectively laminated on front and back sides of the core substrate 40 (FIG. 1 illustrates only one build-up part 12). The core substrate 40 includes an insulating base material (40K) and core conductive layers (40D) that are respectively laminated on front and back sides of the insulating base material (40K).

In the build-up part 12, in order from the core substrate 40 side, a first insulating layer (14A), a first conductive layer (13A), a second insulating layer (14B), a third insulating layer (14C), a second conductive layer (13B), and a solder resist layer 11 are sequentially laminated. In the following, in the build-up part 12 illustrated in FIG. 1, a side where the solder resist layer 11 is provided is referred to as an upper side, and the core substrate 40 side is referred to as a lower side.

For each of the first, second and third insulating layers (14A, 14B, 14C), a prepreg, an insulating film, or the like can be used. For each of the first and second conductive layers (13A, 13B), a plating or the like can be used. However, the present invention is not limited to this.

A cavity 20 is formed in the second insulating layer (14B). The cavity 20 has a quadrangular opening shape. An inner wall (20A) of the cavity 20 is inclined so as to be narrowed from an opening edge toward the first insulating layer (14A).

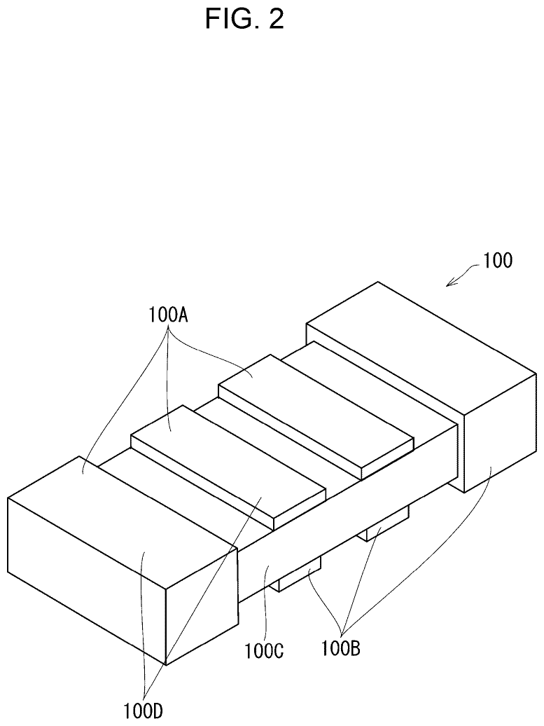

An electronic component 100 is accommodated in the cavity 20 with a gap (20B) between the electronic component 100 and the inner wall (20A). The electronic component 100 is, for example, a capacitor, and, as illustrated in FIG. 2, has a quadrangular chip shape in a front view. The electronic component 100 has a main body part (100C), multiple first electrodes (100A) provided on an upper surface thereof, and multiple second electrodes (100B) provided on a lower surface thereof. Further, the first and second electrodes (100A, 100B) protrude from the main body part (100C), and ends thereof in a protruding direction are flat surfaces (100D). Further, as illustrated in FIG. 1, the flat surfaces (100D) of the first electrodes (100A) are flush with an upper surface of the second insulating layer (14B). In the electronic component 100 of the present embodiment, the first and second electrodes (100A, 100B) provided at each of left and right ends of the electronic component 100 are connected.

Further, multiple pads 15 are exposed at a bottom part of the cavity 20. The multiple pads 15 are each a part of the first conductive layer (13A) and protrude from the first insulating layer (14A), and upper surfaces thereof are flat surfaces (15D). The multiple pads 15 are respectively connected to the second electrodes (100B) of the electronic component 100. A connection structure between the pads 15 and the second electrodes (100B) will be described in detail later.

Without being limited to a capacitor, the electronic component 100 may also be an IC chip, a semiconductor element, a resistor, an inductor or the like, or some components other than these.

The third insulating layer (14C) covers the upper surface of the second insulating layer (14B) and the upper surface of the electronic component 100 and fills the gap (20B) in the cavity 20. Further, the second conductive layer (13B) and the first conductive layer (13A) are connected by first via conductors (17A). The first via conductors (17A) are formed penetrating the third insulating layer (14C) and the second insulating layer (14B).

Further, the first electrodes (100A) of the electronic component 100 are connected to the second conductive layer (13B) by second via conductors (17B). The first and second via conductors (17A, 17B) are formed by filling tapered via holes (17H) with plating metal.

Metal posts 19 are formed on an upper surface of the solder resist layer 11. The metal posts 19 each include a copper plating film (19A), a nickel plating film (not illustrated) laminated on an upper surface of the copper plating film (19A), and a tin plating film (19B) laminated on an upper surface of the nickel plating film.

Further, the metal posts 19 are connected to the second conductive layer (13B) by third via conductors (17C) formed penetrating the solder resist layer 11. Similarly to the first and second via conductors (17A, 17B), the third via conductors (17C) are also formed by filling via holes (17H) with plating metal.

Further, mounting components 110 are mounted on the metal posts 19. The mounting components 110 are connected to each other via the electronic component 100. Examples of the mounting components 110 in the present embodiment include CPUs, memories, and the like.

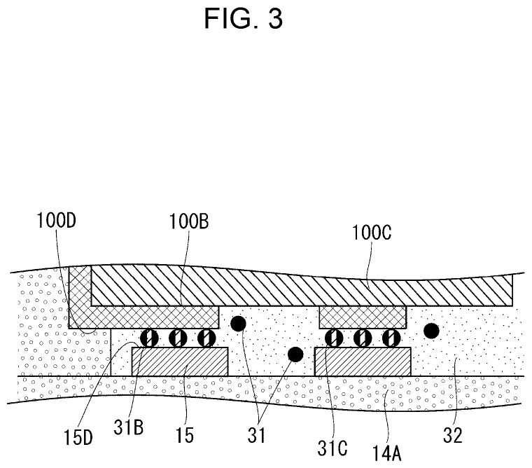

Next, the above-mentioned connection structure between the second electrodes (100B) and the pads 15 is described. As illustrated in FIG. 3, the second electrodes (100B) respectively overlap the pads 15 in an up-down direction, thereby forming a gap between the lower surface of the main body part (100C) of the electronic component 100 and a bottom surface of the cavity 20. And, the gap accommodates a mixture formed by mixing multiple granules 31 in a thermoplastic insulating resin 32.

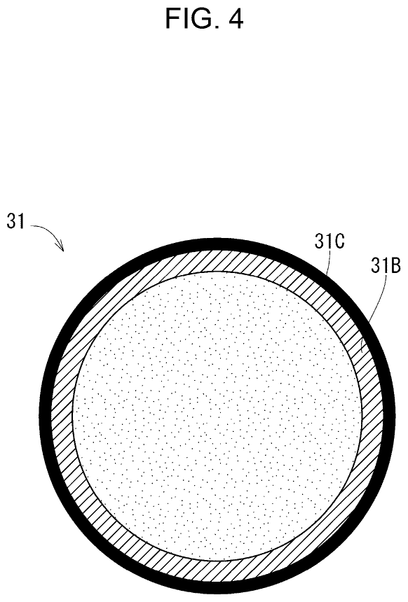

For example, as illustrated in FIG. 4, the granules 31 are each covered with an insulating layer (31C) on an outer side and have a conductive layer (31B) on an inner side thereof. Then, in the above-described gap, the multiple granules 31 of the mixture do not function as conductors, and the insulating resin 32 of the mixture functions as a hot melt adhesive to fix the main body part (100C) of the electronic component 100 to the bottom surface of the cavity 20 while insulating between adjacent second electrodes (100B) and between adjacent pads 15.

The mixture is also provided between the second electrodes (100B) and the pads 15 that overlap in the up-down direction. As illustrated in FIG. 3, the granules 31 of the mixture are sandwiched between the second electrodes (100B) and the pads 15 and pressed against the second electrodes (100B) and the pads 15, with the insulating layer (31C) ruptured and the conductive layer (31B) exposed. As a result, between the second electrodes (100B) and the pads 15, the multiple granules 31 of the mixture function as conductors and form a part of a circuit connecting the second electrodes (100B) and the pads 15. Further, the insulating resin 32 functions as a hot melt adhesive fixing the second electrodes (100B) and the pads 15.

The insulating resin 32 preferably has a melting point of about 110° C.-180° C. Examples thereof include a thermosetting epoxy resin and the like. Further, the conductive layer (31B) of the granules 31 maybe formed of gold, nickel, or other metals.

The description about the connection structure between the second electrodes (100B) and the pads 15 is as given above. Next, a method for manufacturing the wiring substrate 10 of the present embodiment is described.

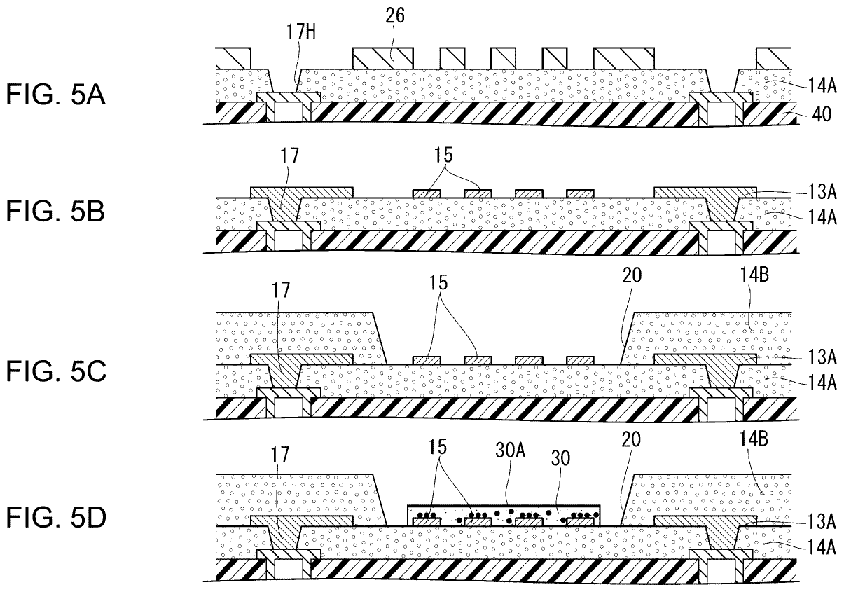

An insulating film as the first insulating layer (14A) may be laminated on the upper surface of the core substrate 40 formed using a commonly known method. Next, the via holes (17H) are formed at predetermined positions in the first insulating layer (14A) using laser or the like, and a desmear treatment is performed in the via holes (17H). Next, a chemical plating treatment is performed, and a chemical plating film (not illustrated) is formed on the first insulating layer (14A) and in the via holes (17H). Next, a plating resist 26 having a predetermined pattern is formed on the chemical plating film (FIG. 5A).

Next, after an electrolytic plating treatment is performed, the plating resist 26 and the chemical plating film are removed, and the first conductive layer (13A) including the pads 15 and via conductors 17 are obtained (FIG. 5B).

It is also possible to use a prepreg as the first insulating layer (14A). In this case, after laminating a copper foil, an electroless plating treatment, a plating resist treatment, and an electrolytic plating treatment are performed on the surface of the insulating film.

An insulating film as the second insulating layer (14B) is laminated on the first conductive layer (13A). Then, as illustrated in FIG. 5C, laser is irradiated to positions corresponding to the pads 15, and the cavity 20 is formed.

A desmear treatment is performed in the cavity 20. Then, an anisotropic conductive film 30 containing the granules 31 in the sheet-like insulating resin 32 is formed at the bottom part of the cavity 20 such that the pads 15 are covered (FIG. 5D). Next, the anisotropic conductive film 30 is thermocompression bonded with a release film (30A) adhered, and fixed to the bottom part of the cavity 20. In the present embodiment, the anisotropic conductive film 30 is in a form of a sheet. However, it is also possible that the anisotropic conductive film 30 is formed of a liquid resin.

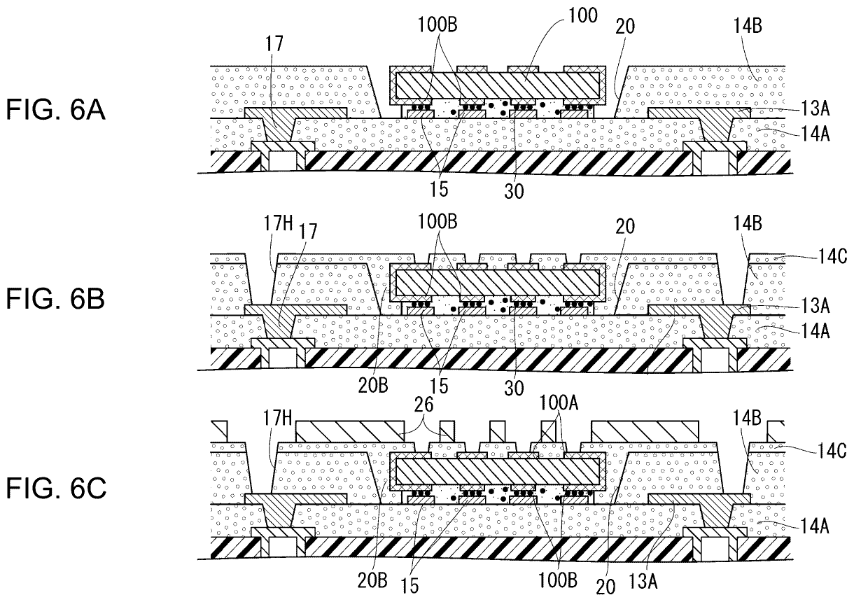

Next, after the release film (30A) is peeled off, the electronic component 100 is accommodated in the cavity 20 using a mounter (FIG. 6A). In this case, the second electrodes (100B) respectively overlap the pads 15. Then, using a bonding tool, the electronic component 100 is thermocompression bonded such that the upper surfaces of the first electrodes (100A) are at the same height as the second insulating layer (14B).

Specifically, when the anisotropic conductive film 30 is sandwiched and hot-pressed between the second electrodes (100B) and the pads 15, the granules 31 are crushed between the flat surfaces (100D) and the flat surfaces(15D). Then, the outermost insulating layers (31C) of the granules are ruptured and the conductive layers (31B) are exposed, and the flat surfaces (100D) and (15D) are connected by the conductive layers (31B).

On the other hand, the granules 31 that are not sandwiched between the flat surfaces (100D) and the flat surfaces (15D) are positioned between the paired second electrodes (100B) and pads 15.

An insulating film as the third insulating layer (14C) is laminated on the second insulating layer (14B), the electronic component 100, and the upper surface of the cavity 20. In this case, a melted resin flows into the gap (20B) in the cavity 20. Then, laser is irradiated to predetermined positions in the third insulating layer (14C) and the via holes (17H) are formed penetrating the third insulating layer (14C) and the second insulating layer (14B) (FIG. 6B).

After a desmear treatment is performed, a chemical plating treatment is performed and a chemical plating film (not illustrated) is formed on the third insulating layer (14C) and in the via holes (17H). Then, a plating resist 26 having a predetermined pattern is formed on the chemical plating film (FIG. 6C).

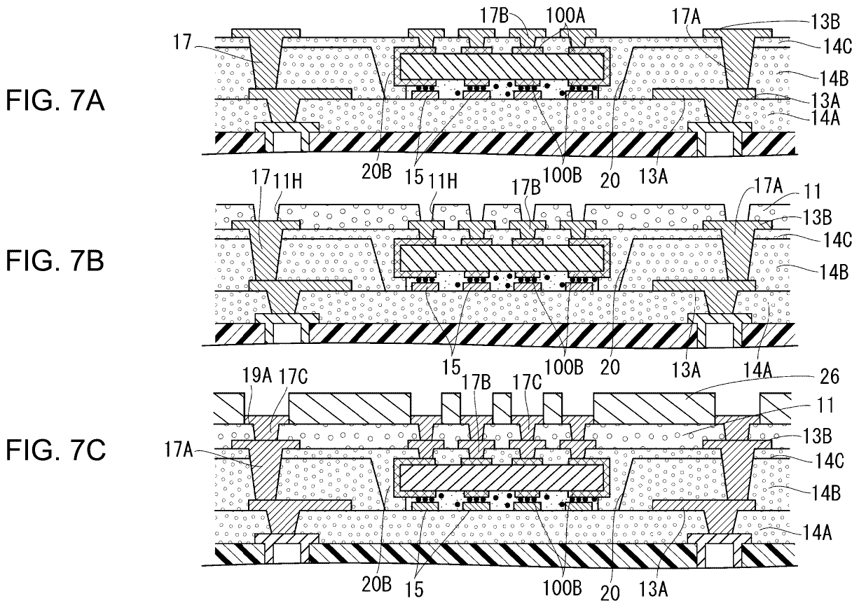

Next, after an electrolytic plating treatment is performed, the plating resist and the chemical plating film are removed, and the second conductive layer (13B) and via conductors 17 are obtained (FIG. 7A). In this case, the via conductors 17 connected to the first conductive layer (13A) become the first via conductors (17A), and the via conductors 17 connected to the first electrodes (100A) become the second via conductors (17B).

The solder resist layer 11 is laminated on the second conductive layer (13B). Next, laser processing, or photolithography processing or the like is performed on the solder resist layer 11 to form openings (11H) (FIG. 7B).

After a chemical plating treatment is performed to form a chemical plating film (not illustrated) on the solder resist layer 11 and in the openings (11H), a plating resist 26 is formed on the chemical plating film. Next, by an electrolytic plating treatment, the openings (11H) are filled with copper plating to form the third via conductors (17C), and the copper plating film (19A) is formed in portions exposed from the plating resist 26 (FIG. 7C). Next, an electrolytic plating treatment is performed, and the nickel plating film (not illustrated) is formed on the copper plating films (19A).

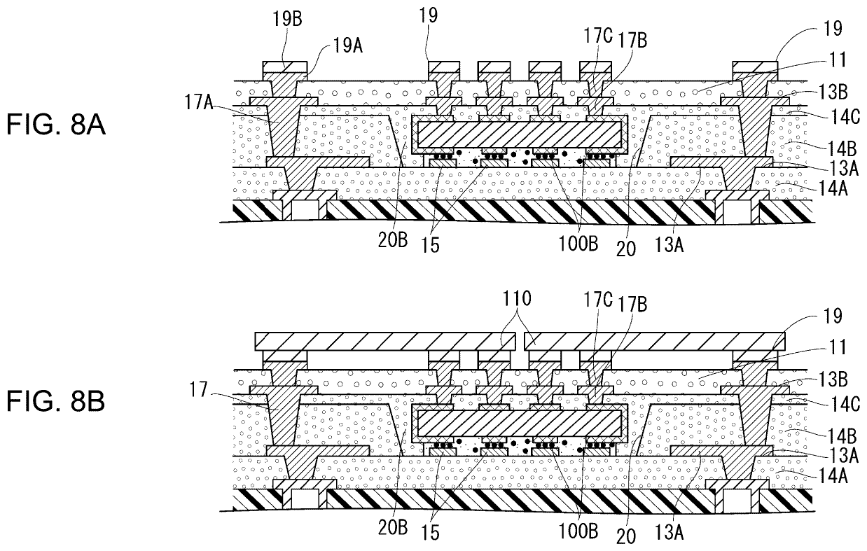

Next, after the tin plating film (19B) is formed on the nickel plating film by an electrolytic plating treatment, the chemical plating film and the plating resist 26 are removed. As a result, the metal posts 19 formed of the copper plating films (19A), the nickel plating film, and the tin plating film (19B) are obtained(FIG. 8A).

The mounting components 110 are mounted on the metal posts 19 using a mounter (FIG. 8B). As a result, the wiring substrate 10 is completed.

The description about the structure and manufacturing method of the wiring substrate 10 of the present embodiment is as given above. Next, operational effects of the wiring substrate 10 are described. In the wiring substrate 10 of the present embodiment, the first electrodes (100A) on the upper surface of the electronic component 100 are connected to the second conductive layer (13B) via the second via conductors (17B). Further, the second electrodes (100B) on the lower surface of the electronic component 100 are connected to the first conductive layer (13A) via the multiple granules 31 sandwiched therebetween. As a result, the electrodes on the upper surface and the lower surface of the electronic component 100 are electrically connected to the circuits of the wiring substrate 10.

Further, the via conductors are used to connect the first electrodes (100A) on the upper surface of the electronic component 100 and a conductive connecting part other than via conductors is used to connect the second electrodes (100B) on the lower surface of the electronic component 100. Thereby, the cavity 20 can be provided in the build-up part 12 instead of the core substrate 40. Specifically, in order to also connect via conductors to the second electrodes (100B) on the lower surface of the electronic component 100 in the same way as the first electrodes (100A) on the upper surface, a cavity penetrating the core substrate 40 is provided. However, according to the structure of the wiring substrate 10 of the present embodiment, this is no longer necessary, and the cavity can be provided in the build-up part 12 as described above. Further, as a result, a circuit connecting the second electrodes (100B) on the lower surface of the electronic component 100 and the mounting components 110 on the build-up part 12 can be shortened. Further, in order for via conductors to be connected to the electrodes on both the upper and lower sides of the electronic component 100, the electronic component 100 is sandwiched between a pair of insulating layers for forming the via conductors. However, according to the structure of the wiring substrate 10 of the present embodiment, one insulating layer is formed for forming such via conductors, and thus, the entire wiring substrate 10 can be formed thinner.

In the case where the electronic component 100 is accommodated in a cavity penetrating the core substrate 40, it is also possible to adopt a structure in which via conductors are used to connect the electrodes on one of the front and back (upper and lower) sides of the electronic component 100 and a conductive connecting part other than via conductors is used to connect the electrodes on the other one of the front and back (upper and lower) sides.

Further, the connecting portion between the second electrodes (100B) and the pads 15 contains the insulating resin 32. The insulating resin 32, with the multiple granules 31 dispersed therein, is formed between the lower surface of the electronic component 100 (excluding the second electrodes (100B)) and the upper surface of the first conductive layer (13A). According to this, the granules 31 positioned between pairs of the second electrodes (100B) and the pads 15 that are adjacent to each other in the left-right direction function together with the insulating resin 32 as an insulator, and thus, a short circuit between the pairs of the second electrodes (100B) and the pads 15 can be suppressed.

Further, a connecting portion between the second electrodes (100B) and the first conductive layer (13A) including the pads 15 is the anisotropic conductive film 30. According to this, the adhesion of the electronic component 100, the conduction between the second electrodes (100B) and the pads 15, and the insulation between the pairs of the second electrodes (100B) and the pads 15, can be performed using only the anisotropic conductive film 30, and thus, work can be simplified.

### Second Embodiment

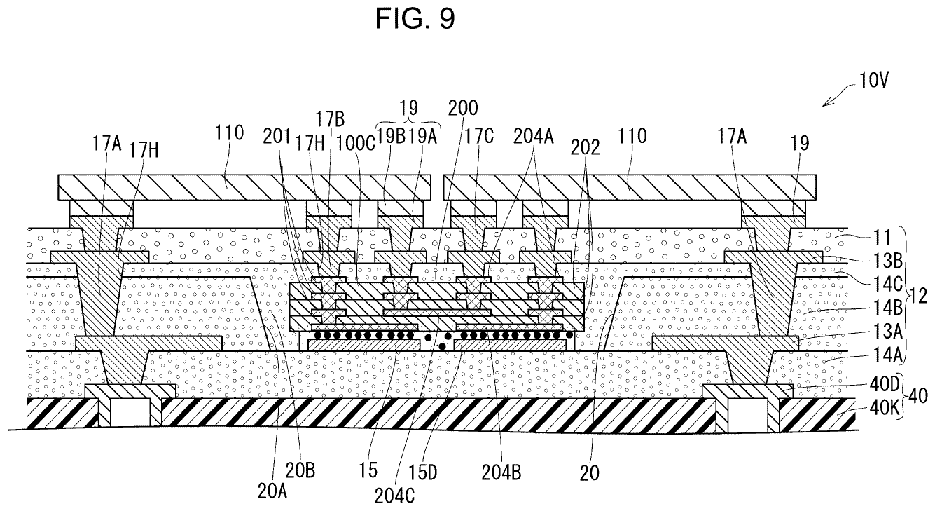

A wiring substrate (10V) of the present embodiment differs from the first embodiment in that the electronic component 100 described above is a wiring structure 200 as illustrated in FIG. 9. The wiring structure 200 is a laminated structure and includes multiple wiring layers 201 and multiple interlayer insulating layers 202.

The wiring layers 201 include multiple pads 204, among which lower pads (204B) positioned on a lower side are connected to the pads 15, and upper pads (204A) positioned on an upper side are connected to the second conductive layer (13B) via the second via conductors (17B). Further, the wiring layers 201 separated by the interlayer insulating layer 202 are connected by via conductors 203. The wiring layers 201 include wirings (204C) that connect between the mounting components 110. And, the wiring layers 204 and the via conductors have smaller wiring widths and inter-wiring distances than the wiring substrate (10V).

### Other Embodiments

In the wiring substrate 10 of the present embodiment, the second electrodes (100B) and the pads 15 are electrically connected by the granules 31 contained in the anisotropic conductive film 30. However, it is also possible that the second electrodes (100B) and the pads 15 are electrically connected by solder. In this case, cream solder is printed on the pads 15 or on the second electrodes (100B), and, after the electronic component 100 is accommodated in the cavity 20, the second electrodes (100B) and the pads 15 are connected through a reflow process.

When the second electrodes (100B) and the pads 15 are connected by solder, the electronic component 100 is mounted at temperatures about 200° C.-260° C. However, when the second electrodes (100B) and the pads 15 are connected using the anisotropic conductive film 30 as in the present embodiment, the electronic component 100 can be mounted at lower temperatures about 110° C.-180° C.

In the wiring substrate 10 of the present embodiment, the electronic component 100 has a quadrangular shape in a front view. However, it is also possible that the electronic component 100 has a circular shape or other polygonal shapes. Further, the opening shape of the cavity 20 maybe changed to match the shape of the electronic component 100.

Further, the inner wall (20A) of the cavity 20 is inclined so as to be narrowed toward the first insulating layer (14A). However, the present invention is not limited to this. For example, it is also possible that the cavity 20 is a cube-shaped recess.

In the wiring substrate 10 of the present embodiment, the first insulating layer (14A) is directly laminated on the core substrate 40. However, it is also possible that the first insulating layer (14A) is laminated after multiple insulating layers and multiple conductive layers have been alternately laminated on the core substrate 40.

In the wiring substrate 10 of the present embodiment, multiple mounting components 110 are provided. However, it is also possible that only one mounting component 110 is provided or no mounting component 110 is provided.

In a wiring substrate, a lower surface of the electronic component that does not have electrodes may be fixed to a bottom surface of the cavity with an adhesive. Then, multiple via holes are formed in an insulating layer that covers the cavity from above, and via conductors formed of plating metal in the via holes connect electrodes on an upper surface of the electronic component to electrical circuits of the wiring substrate (for example, see Japanese Patent Application Laid-Open Publication No. 2019-192730).

A wiring substrate according to an embodiment of the present invention includes a first insulating layer, a first conductive layer that partially covers an upper surface of the first insulating layer, a second insulating layer that is laminated on the first insulating layer with the first conductive layer sandwiched in between, a cavity that penetrates the second insulating layer and exposes the first conductive layer, an electronic component that is accommodated in the cavity and has first electrodes on an upper surface thereof and second electrodes on a lower surface thereof, a third insulating layer that is laminated on the second insulating layer and fills the cavity, via conductors that penetrate the third insulating layer and connect to the first electrodes, pads that are included in the first conductive layer and connect to the second electrodes in the cavity, and a conductive connecting part other than via conductors that is provided between the second electrodes and the pads and electrically connects the second electrodes and the pads.

In a wiring substrate according to an embodiment of the present invention, it becomes possible to incorporate an electronic component having electrodes on both upper and lower surfaces thereof in the wiring substrate, and to connect circuits of the wiring substrate to the electrodes.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first insulating layer;
a first conductive layer laminated on a surface of the first insulating layer and including a plurality of pads;
a second insulating layer laminated on the first insulating layer such that the second insulating layer is covering the first conductive layer and has a cavity exposing the pads of the first conductive layer;
an electronic component accommodated in the cavity of the second insulating layer such that the electronic component has a plurality of electrodes formed on a surface of the electronic component; and
a conductive connecting part formed between the electrodes of the electronic components and the pads of the first conductive layer in the cavity of the second insulating layer such that the conductive connecting part electrically connects the electrodes of the electronic components and the pads of the first conductive layer.

2. The wiring substrate according to claim 1, wherein the connecting part includes granules and an insulating resin.

3. The wiring substrate according to claim 2, wherein the connecting part is formed such that the insulating resin is formed between the surface of the electronic component and the surface of the first insulating layer in the cavity of the second insulating layer and that the granules are dispersed substantially throughout the insulating resin.

4. The wiring substrate according to claim 1, wherein the first conductive layer is formed such that the pads are positioned to connect to the electrodes of the electronic component respectively.

5. The wiring substrate according to claim 1, wherein the connecting part includes an anisotropic conductive film.

6. The wiring substrate according to claim 1, further comprising:
a third insulating layer laminated on the second insulating layer such that the third insulating layer is filling a space between the electronic component and the second insulating layer in the cavity; and
a plurality of via conductors formed in the third insulating layer such that the plurality of via conductors is connecting to a plurality of electrodes formed on a surface of the electronic component on an opposite side with respect to the surface of the electronic component facing the first conductive layer.

7. The wiring substrate according to claim 6, wherein the electronic component is a wiring structure configured to interconnect a plurality of mounting components.

8. The wiring substrate according to claim 1, wherein the electronic component is a capacitor or an inductor.

9. The wiring substrate according to claim 1, wherein the electronic component is positioned in the cavity of the second insulating layer such that the electronic component has a surface that is flush with a surface of the second insulating layer on an opposite side with respect to the surface of the electronic component facing the first conductive layer.

10. The wiring substrate according to claim 6, wherein the third insulating layer is an outermost insulating layer of the wiring substrate.

11. The wiring substrate according to claim 2, wherein the first conductive layer is formed such that the pads are positioned to connect to the electrodes of the electronic component respectively.

12. The wiring substrate according to claim 2, wherein the connecting part includes an anisotropic conductive film.

13. The wiring substrate according to claim 2, further comprising:
a third insulating layer laminated on the second insulating layer such that the third insulating layer is filling a space between the electronic component and the second insulating layer in the cavity; and
a plurality of via conductors formed in the third insulating layer such that the plurality of via conductors is connecting to a plurality of electrodes formed on a surface of the electronic component on an opposite side with respect to the surface of the electronic component facing the first conductive layer.

14. The wiring substrate according to claim 13, wherein the electronic component is a wiring structure configured to interconnect a plurality of mounting components.

15. The wiring substrate according to claim 2, wherein the electronic component is a capacitor or an inductor.

16. The wiring substrate according to claim 2, wherein the electronic component is positioned in the cavity of the second insulating layer such that the electronic component has a surface that is flush with a surface of the second insulating layer on an opposite side with respect to the surface of the electronic component facing the first conductive layer.

17. The wiring substrate according to claim 13, wherein the third insulating layer is an outermost insulating layer of the wiring substrate.

18. The wiring substrate according to claim 3, wherein the connecting part includes an anisotropic conductive film.

19. The wiring substrate according to claim 3, further comprising:
a third insulating layer laminated on the second insulating layer such that the third insulating layer is filling a space between the electronic component and the second insulating layer in the cavity; and
a plurality of via conductors formed in the third insulating layer such that the plurality of via conductors is connecting to a plurality of electrodes formed on a surface of the electronic component on an opposite side with respect to the surface of the electronic component facing the first conductive layer.

20. The wiring substrate according to claim 19, wherein the electronic component is a wiring structure configured to interconnect a plurality of mounting components.
